(19) United States
(12) Patent Application Publication
(10) Pub. No.: US 2025/0337394 A1
(43) Pub. Date: Oct. 30, 2025

(54) SEMICONDUCTOR DEVICE

(71) Applicant: Renesas Electronics Corporation, Tokyo (JP)

(72) Inventor: Ryutaro MINESAWA, Tokyo (JP)

(73) Assignee: Renesas Electronics Corporation, Tokyo (JP)

(21) Appl. No.: 19/181,866

(22) Filed: Apr. 17, 2025

(30) Foreign Application Priority Data
Apr. 26, 2024 (JP) 2024-072403

(51) Int. Cl. H03K 3/012; H03K 17/04

(52) U.S. Cl. CPC H03K 3/012; H03K 17/04

(57) ABSTRACT

A semiconductor device is provided. The semiconductor devices is connected to a power device. The semiconductor device includes a gate driver unit with a first circuit and a second circuit, a resistor unit connecting the gate of the power device and the gate driver unit, and a first control circuit connected to the gate driver unit. The first control circuit is configured to increase the resistance of the power device by issuing an instruction to reduce the slew rate of the power device to the first circuit during the turn-off of the power device.

### CROSS-REFERENCE TO RELATED APPLICATION

The disclosure of Japanese Patent Application No. 2024-072403 filed on Apr. 26, 2024, including the specification, drawings and abstract is incorporated herein by reference in its entirety.

### BACKGROUND

The present disclosure relates to a semiconductor device and is particularly suitable for use in a semiconductor device incorporating a gate driver unit for power devices.

In traction motor systems, achieving further high efficiency (reduction of power loss) is important for realizing carbon neutrality. By improving the efficiency of traction motor systems, it is possible to extend the driving range per charge and enhance the convenience of xEVs (such as EVs: Electric Vehicles and PHEVs: Plug-in Hybrid Electric Vehicles).

Additionally, to increase the efficiency of inverters installed in traction motor systems, the adoption of IGBTs (Insulated Gate Bipolar Transistors) and SiC-MOSFETs (Silicon Carbide Metal-Oxide-Semiconductor Field-Effect Transistors) with low power loss is progressing. To improve the efficiency of inverters, it is necessary to reduce conduction loss and switching loss.

To reduce switching loss, increasing the switching speed can lead to the occurrence of noise and ringing during turn-off, resulting in issues from the perspective of electromagnetic interference (EMI), such as communication errors with vehicle systems and the generation of disruptive radio waves.

### SUMMARY

Therefore, there is a demand for a semiconductor device that can achieve both high-speed switching and suppression of electromagnetic interference. Other problems and novel features will become apparent from the description of this specification and the accompanying drawings.

According to one embodiment, the semiconductor device achieves both high-speed switching and suppression of electromagnetic interference by incorporating a state that increases the resistance of the power device during its turn-off, thereby consuming the energy generated by stray inductance without the need for additional circuits.

According to the aforementioned embodiment, it is possible to provide a semiconductor device that can achieve both high-speed switching and suppression of electromagnetic interference.

### BRIEF DESCRIPTION OF THE DRAWINGS

FIG. 1 is a block diagram of a semiconductor device according to a first embodiment.

FIG. 2 is a diagram explaining the mechanism of ringing in a power device.

FIGS. 3A and 3B are diagrams explaining the mechanism of ringing in the power device.

FIG. 4 is a diagram illustrating waveforms during the turn-off of the power device.

FIGS. 5A and 5B are diagrams explaining the operation of the semiconductor device according to the first embodiment.

FIGS. 6A, 6B and 6C are diagrams explaining the electrical characteristics of the power device according to the first embodiment.

FIGS. 7A and 7B are diagrams explaining the electrical characteristics of the power device according to the first embodiment.

FIG. 8 is a block diagram of the semiconductor device according to the first embodiment.

FIG. 9 is a block diagram of the semiconductor device according to the first embodiment.

FIG. 10 is a block diagram of the semiconductor device according to the first embodiment.

FIG. 11 is a block diagram of the semiconductor device according to the first embodiment.

FIG. 12 is a block diagram of a semiconductor device according to a second embodiment.

FIGS. 13A and 13B are diagrams explaining the electrical characteristics of a power device according to the second embodiment.

FIG. 14 is a block diagram of the semiconductor device according to the second embodiment.

FIG. 15 is a block diagram of the semiconductor device according to the second embodiment.

FIG. 16 is a block diagram of the semiconductor device according to the second embodiment.

### DETAILED DESCRIPTION

Hereinafter, embodiments of the present disclosure will be described in detail with reference to the drawings. In the specification and drawings, the same or corresponding components are denoted by the same reference numerals, and repetitive descriptions thereof may be omitted. In the drawings, for convenience of description, the configuration may be omitted or simplified. Also, at least some of the embodiments may be arbitrarily combined with each other.

### First Embodiment

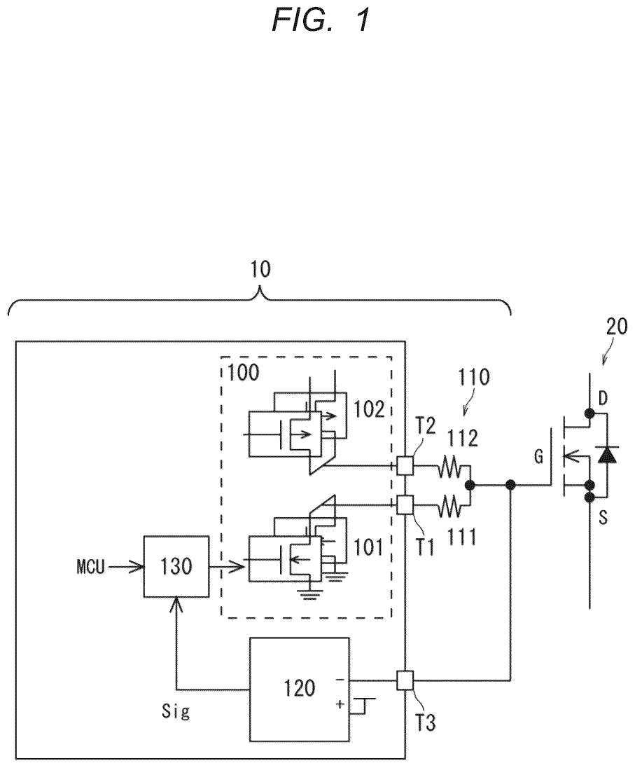

FIG. 1 is a block diagram of a semiconductor device according to a first embodiment. The semiconductor device 10 is connected to a power device 20 and includes a gate driver unit 100, a resistor unit 110, a detection circuit 120, and a control circuit 130.

In the example illustrated in FIG. 1, the power device 20 is described as a MOSFET having a gate (“G” in FIG. 1), a source (“S” in FIG. 1), and a drain (“D” in FIG. 1), but the present disclosure is not limited thereto and is also suitable for IGBTs and the like. Examples of MOSFETs include SiC-MOSFETs, Si-MOSFETs, and GaN-MOSFETs.

The gate driver unit 100 includes at least a first circuit 101 and a second circuit 102. The resistor unit 110 includes at least a first resistor 111 and a second resistor 112. The first circuit 101 and the first resistor 111 are connected to each other via terminal T1, and the second circuit 102 and the second resistor 112 are connected to each other via terminal T2.

The first circuit 101 and the second circuit 102 are each a multi-level gate driver circuit having at least two stages of High and Low. By doing so, in high-load regions where EMI occurs, it is possible to suppress EMI (electromagnetic interference) by reducing the switching speed of the power device by 20.

Also, the first resistor 111 and the second resistor 112 are coupled to each other at the terminal on the side not connected to the gate driver unit 100 and are connected to the gate of the power device 20. In this way, the resistor unit 110 connects the gate of the power device 20 and the gate driver unit 100.

The detection circuit 120 includes a monitor unit and a comparator. The monitor unit is configured to observe at least one of the gate voltages of the power device 20, the voltage between the source and drain, and the load current. The monitor unit may be provided as a separate circuit external to the semiconductor device 10, but if it is built into the detection circuit 120, additional components are unnecessary, allowing for miniaturization of the semiconductor device 10.

The comparator is configured to compare the electrical characteristics of the power device 20 observed by the monitor unit with a predetermined threshold set in the comparator, and to send a signal Sig to the control circuit 130 when a comparison result satisfying the set conditions is obtained.

The control circuit 130 is configured to issue an instruction to reduce the slew rate of the first circuit 101 during the turn-off of the power device 20, based on the results obtained by the detection circuit 120. The control circuit 130 may be configured with a logic circuit and may be connected to a microcontroller unit (MCU).

In the example of the semiconductor device 10 shown in FIG. 1, the monitor unit observes the gate voltage of the power device 20 via terminal T3, and the comparator is configured to compare the observed gate voltage with a predetermined threshold.

The comparator sends a signal Sig to the control circuit 130 when the gate voltage of the power device 20 falls below a predetermined first threshold. Upon receiving the signal Sig, the control circuit 130 instructs the first circuit 101 to reduce the slew rate of the gate of the power device 20, causing the first circuit 101 to increase the resistance between the source and drain of the power device 20.

Here, the operation performed by the semiconductor device 10 according to this disclosure on the power device 20 will be described.

The semiconductor device 10 according to this disclosure intentionally introduces a high-resistance state in the power device 20 during its turn-off, thereby forming an LRC series circuit (L: inductor, R: resistor, C: capacitor) within the power module. As a result, the energy generated in the parasitic inductance within the power module is consumed by the power device 20, allowing for the suppression of EMI.

In other words, the semiconductor device 10 according to this disclosure can be configured to pseudo-implement a snubber circuit or bypass capacitor. Actually, providing a snubber circuit or bypass capacitor around the power device 20 would lead to issues such as increased size and cost of the semiconductor device 10 and the power device 20. On the other hand, the semiconductor device 10 according to this disclosure can suppress EMI without adding these circuits.

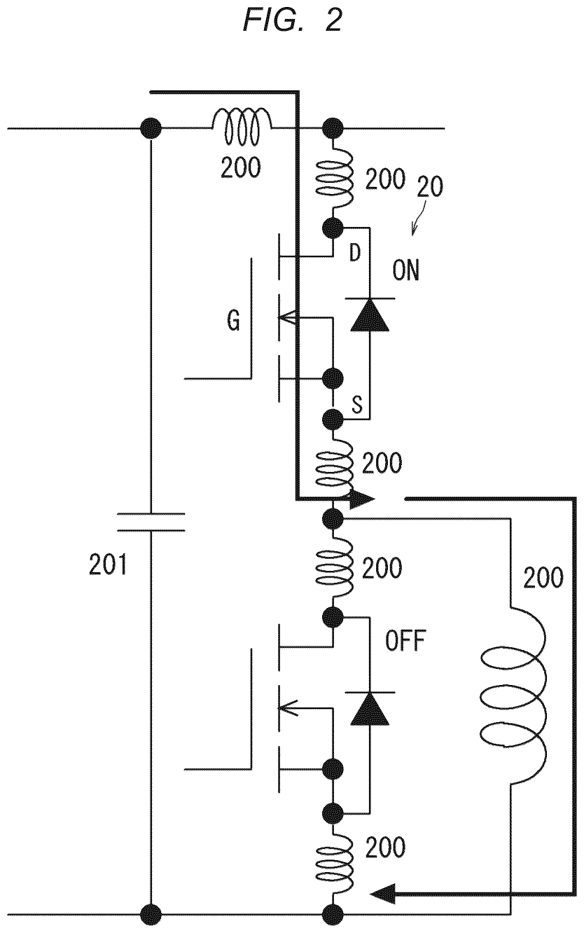

Here, the mechanism of ringing occurrence will be explained. FIG. 2 shows the power device 20 in an on (conducting) state. At this time, energy (E=½*L*I\hat{ }2, I: current) is stored in a parasitic inductor 200 around the power device 20.

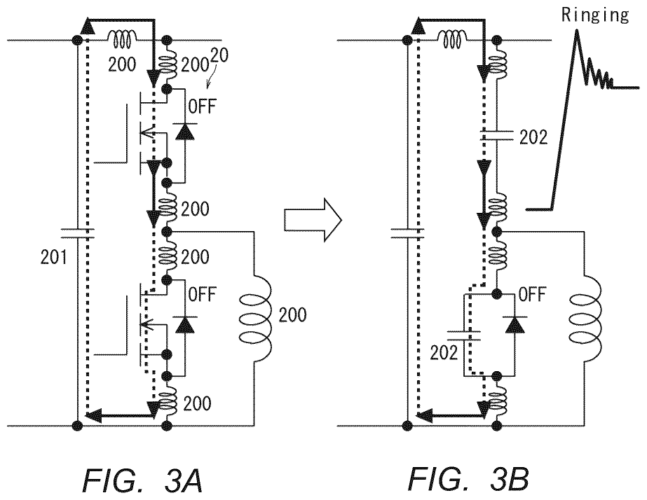

FIG. 3A shows the moment when the power device 20 is turned off. At this time, the power device 20 is in a state replaced by a capacitor 202 (see FIG. 3B). The energy stored in the parasitic inductor 200 has nowhere to go other than the parasitic inductor 200 and a bypass capacitor 201 provided in the power device 20, causing LC resonance and resulting in ringing.

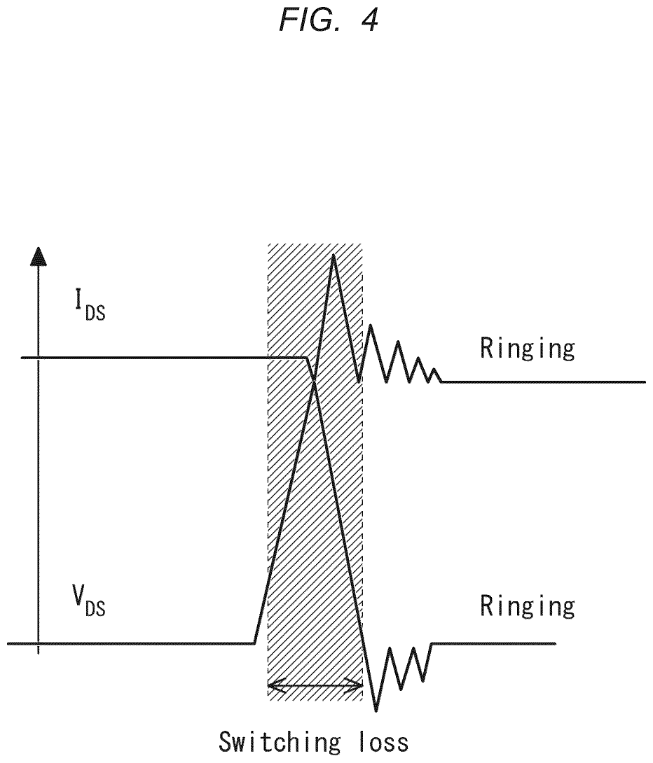

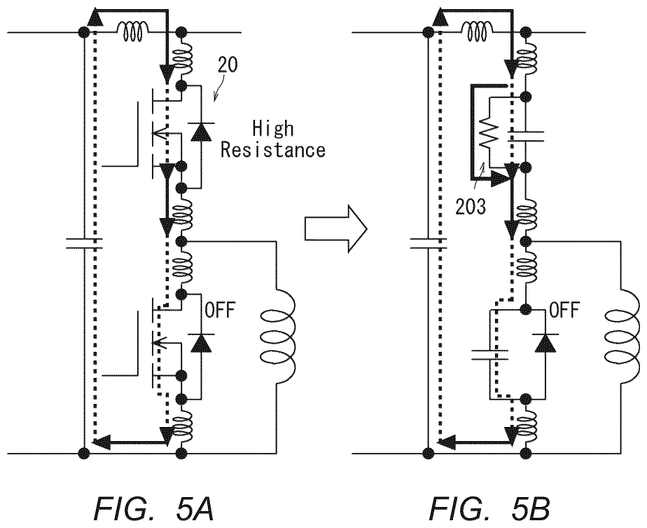

FIG. 4 shows the waveform at turn-off, and FIGS. 5A and 5B shows the high-resistance state of the power device 20 by the semiconductor device 10 according to this disclosure. At the timing when ringing occurs, the power device 20 is made of high resistance (see FIG. 5A), converting the power device 20 itself into a resistive component 203, and pseudo-forming an LRC series circuit without additional circuits (see FIG. 5B). This allows the energy stored in the parasitic inductor 200 to be dissipated by the LRC series circuit.

This makes it possible to appropriately increase the resistance between the source and drain of the power device 20 at turn-off, thereby suppressing EMI.

Subsequently, when it is observed by the detection circuit 120 that the gate voltage of the power device 20 has reached a level (second threshold) where the influence of ringing on the power device 20 is eliminated, the control circuit 130 stops the reduction of the slew rate of the gate of the power device 20. Maintaining a high-resistance state between the source and drain of the power device 20 to suppress EMI results in a decrease in switching speed due to the high resistance of the power device 20. Therefore, by returning the power device 20 to its normal state when the influence of ringing is eliminated, it is possible to suppress the decrease in switching speed, achieving both high-speed switching and suppression of electromagnetic interference.

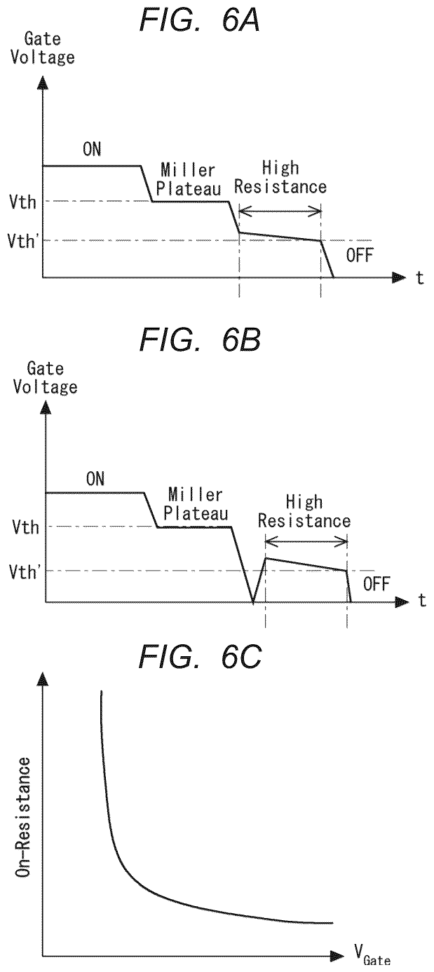

The high-resistance state between the source and drain of the power device 20 will be explained with reference to FIGS. 6A, 6B and 6C. FIGS. 6A and 6B respectively represent the time change of the gate voltage when the power device 20 is turned off. Two timings can be considered for making the resistance between the source and drain of the power device 20 high.

One is, as shown in FIG. 6A, to make the resistance between the source and drain of the power device 20 high during turn-off. When the power device 20 switches, a Miller plateau period (referred to as “Miller Plateau” in FIG. 6A) occurs where the gate voltage of the power device 20 does not decrease linearly but is maintained at a certain value, and the gate voltage during this period is called the Miller plateau voltage.

In the example of the semiconductor device shown in FIG. 1, this Miller plateau voltage is used as the first threshold (referred to as “Vth” in FIG. 6A) set in the comparator. Therefore, when it is observed that the gate voltage of the power device 20 has fallen below the Miller plateau voltage, the control circuit 130 reduces the slew rate of the gate of the power device 20, making the resistance between the source and drain of the power device 20 high (referred to as “High Resistance” in FIG. 6A).

Also, when it is observed that the voltage at which the influence of ringing on the power device 20 is eliminated (second threshold, referred to as “Vth” in FIG. 6A) is reached, the control circuit 130 stops the reduction of the slew rate of the gate of the power device 20, quickly turning off the power device 20. This allows the suppression of the decrease in switching speed due to the high resistance of the power device 20.

The first threshold and the second threshold are not limited to the above examples and can be arbitrarily changed and may also be fixed values. Changes to the first threshold and the second threshold can be made from register settings inside the gate driver unit 100, primary-side setting pins, secondary-side setting pins, etc. The primary-side setting pins and secondary-side setting pins will be described later.

By adjusting the gate voltage of the power device 20, it is possible to adjust the on-resistance of the power device 20. FIG. 6C shows the relationship between the gate voltage and the on-resistance of the power device 20. By lowering the gate voltage, the resistance between the source and drain of the power device 20 can be made high.

Another method, as shown in FIG. 6B, is to turn the power device 20 back on after turn-off, making the resistance between the source and drain of the power device 20 high. The details of this will be explained in the embodiment described later.

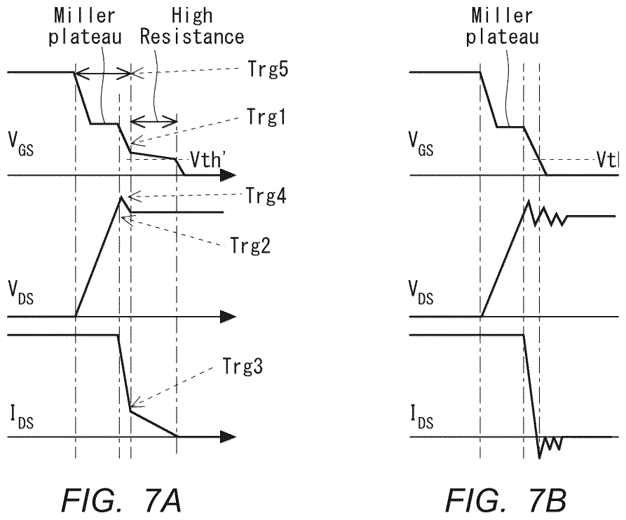

FIGS. 7A and 7B show the electrical characteristics of the power device 20 in the case where the resistance between the source and drain of the power device 20 is made high (hereinafter referred to as “high-resistance mode”) by the semiconductor device 10 according to this embodiment, alongside the electrical characteristics of a comparative example considered by the inventor. FIG. 7A shows the high-resistance mode, and FIG. 7B shows the comparative example, each illustrating the time change of the gate voltage, the voltage between the source and drain, and the load current of the power device 20. As shown in FIG. 7B, in the power device 20 of the comparative example, ringing occurs in the voltage between the source and drain and the load current.

In the example of the power device 20 shown in FIG. 1, the point at which the gate voltage falls below the Miller plateau voltage is used as a trigger (referred to as “Trg1” in FIG. 7A), causing the slew rate to decrease and entering the high-resistance mode by the semiconductor device 10. It can be seen that the inclusion of the high-resistance mode period suppresses the ringing in the voltage between the source and drain and the load current.

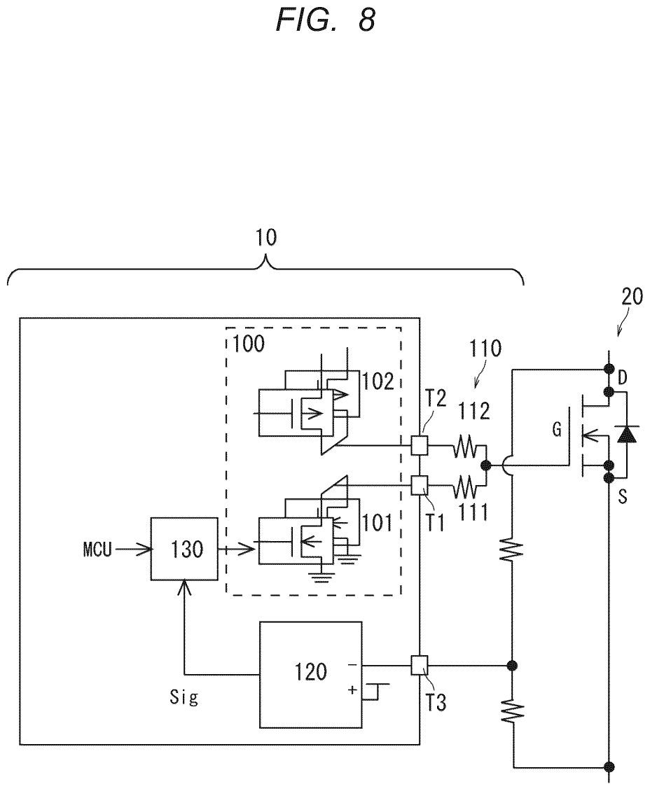

Next, an example of operating the semiconductor device 10 using the voltage between the source and drain of the power device 20 will be described with reference to FIG. 8. In the example of the semiconductor device 10 shown in FIG. 8, the monitor unit observes the voltage between the source and drain of the power device 20 via terminal T3, and the comparator is configured to compare the observed voltage between the source and drain with a predetermined threshold.

As shown in FIGS. 7A and 7B, when the power device 20 is turned off, the voltage between the source and drain rises linearly even during the period when the gate voltage is the Miller plateau voltage.

The comparator sends a signal Sig to the control circuit 130 when the voltage between the source and drain of the power device 20 exceeds a predetermined threshold. Upon receiving the signal Sig, the control circuit 130 instructs the first circuit 101 to reduce the slew rate of the gate of the power device 20, causing the first circuit 101 to increase the resistance between the source and drain of the power device 20.

This allows the resistance between the source and drain of the power device 20 to be appropriately increased during turn-off, thereby enabling the suppression of EMI.

As shown in the example of FIG. 8, the power device 20 is triggered (as “Trg2” in FIG. 7A) when the voltage between the source and drain exceeds a predetermined threshold, causing the slew rate to decrease and entering a high-resistance mode by the semiconductor device 10. It is understood that the ringing of the voltage and load current between the source and drain is suppressed by the period of the high-resistance mode.

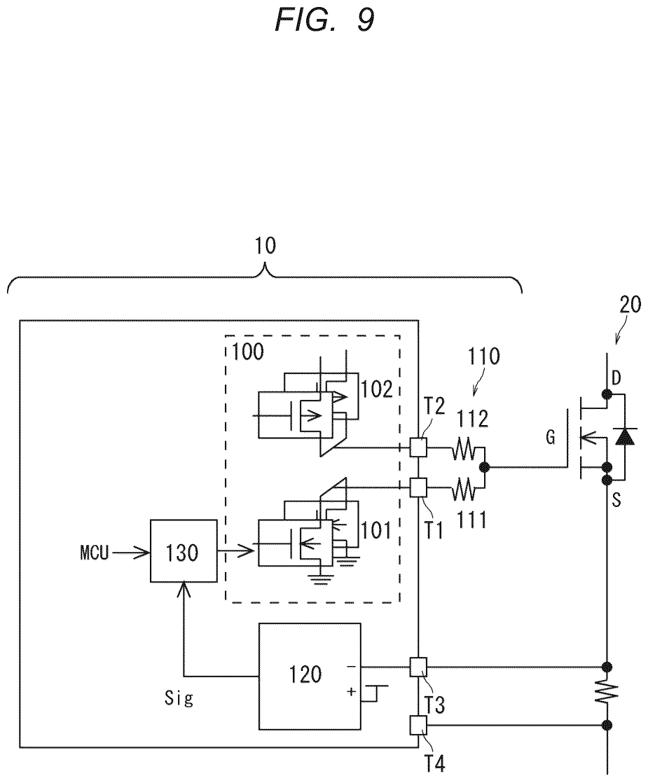

Next, an example of operating the semiconductor device 10 using the load current of the power device 20 will be described with reference to FIG. 9. In the example of the semiconductor device 10 shown in FIG. 9, the monitor unit observes the load current of the power device 20 via terminals T3 and T4, and the comparator is configured to compare the observed load current with a predetermined threshold. Note that the detection of the load current is not limited to the monitor unit and may use the current detection terminal of the power device 20.

As shown in FIGS. 7A and 7B, when the power device 20 turns off and the period where the gate voltage is the Miller plateau voltage passes, the load current decreases linearly.

The comparator sends a signal Sig to the control circuit 130 when the load current of the power device 20 falls below a predetermined threshold. Upon receiving the signal Sig, the control circuit 130 instructs the first circuit 101 to reduce the slew rate of the gate of the power device 20, causing the first circuit 101 to increase the resistance between the source and drain of the power device 20.

This allows the resistance between the source and drain of the power device 20 to be appropriately increased during turn-off, thereby enabling the suppression of EMI.

As shown in the example of FIG. 9, the power device 20 is triggered (as “Trg3” in FIG. 7A) when the load current exceeds a predetermined threshold, causing the slew rate to decrease and entering a high-resistance mode by the semiconductor device 10. It is understood that the ringing of the voltage and load current between the source and drain is suppressed by the period of the high-resistance mode.

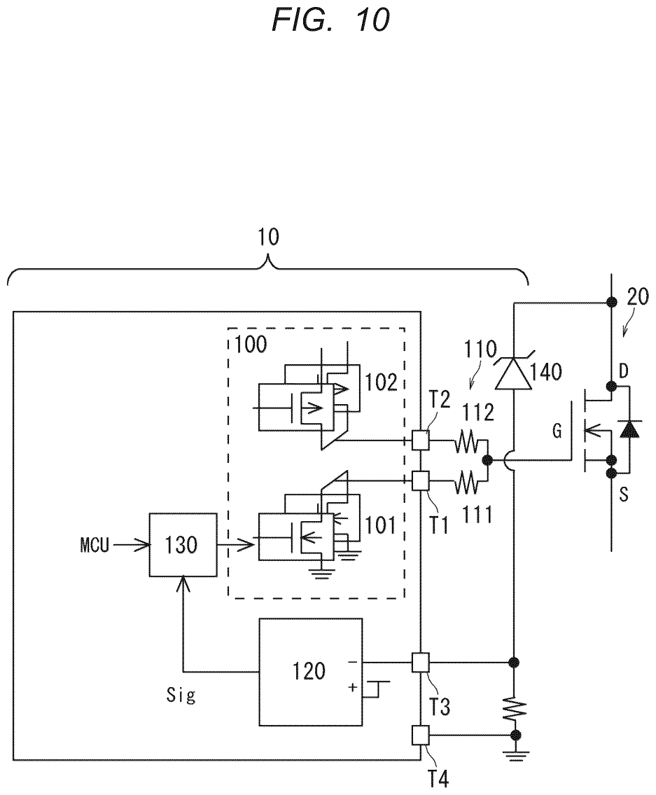

Next, an example of operating the semiconductor device 10 by providing a clamp circuit to the power device 20 will be described with reference to FIG. 10. In the example of the semiconductor device 10 shown in FIG. 10, a Zener diode 140 is provided between the gate and drain of the power device 20. When a surge voltage occurs between the gate and drain of the power device 20, the overvoltage is fixed to a constant voltage by the Zener diode 140, and the excess current (Zener current) flows through the resistance between terminals T3 and T4, allowing the monitor unit to detect the surge voltage.

The comparator sends a signal Sig to the control circuit 130 when the Zener current falls below a predetermined threshold. Upon receiving the signal Sig, the control circuit 130 instructs the first circuit 101 to reduce the slew rate of the gate of the power device 20, causing the first circuit 101 to increase the resistance between the source and drain of the power device 20.

This allows the resistance between the source and drain of the power device 20 to be appropriately increased during turn-off, thereby enabling the suppression of EMI.

As shown in the example of FIG. 10, the power device 20 is triggered (as “Trg4” in FIG. 7A) when a surge voltage occurs between the gate and drain, causing the slew rate to decrease and entering a high-resistance mode by the semiconductor device 10. It is understood that the ringing of the voltage and load current between the source and drain is suppressed by the period of the high-resistance mode.

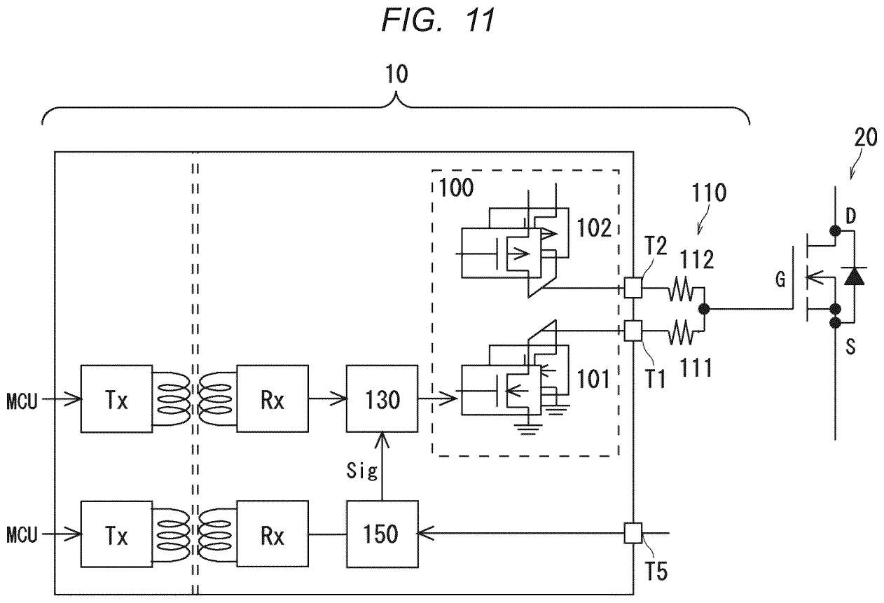

Next, an example of operating the semiconductor device 10 by managing with a timer instead of the detection circuit 120 will be described with reference to FIG. 11. In the example of the semiconductor device 10 shown in FIG. 11, a register circuit 150 with a timer is provided upstream of the control circuit 130. The control circuit 130 and the register circuit 150 may be configured to connect with a microcontroller unit (MCU), and in the configuration illustrated in FIG. 11, they are connected to the MCU via the transmission port Tx on the MCU side and the reception port Rx on the circuit side. The primary setting pin used for changing the first and second thresholds is on the MCU side, and the secondary setting pin indicates the power device side.

When the register circuit 150 detects the start of turn-off of the power device 20 via terminal T5, it sends a signal Sig to the control circuit 130 after a predetermined time has elapsed. Upon receiving the signal Sig, the control circuit 130 instructs the first circuit 101 to reduce the slew rate of the gate of the power device 20, causing the first circuit 101 to increase the resistance between the source and drain of the power device 20.

This allows the resistance between the source and drain of the power device 20 to be appropriately increased during turn-off, thereby enabling the suppression of EMI.

As shown in the example of FIG. 11, the power device 20 is triggered (as “Trg5” in FIG. 7A) at the point after a predetermined time has elapsed following the turn-off of the power device 20, causing the slew rate to decrease and entering a high-resistance mode by the semiconductor device 10. It is understood that the ringing of the voltage and load current between the source and drain is suppressed by the period of the high-resistance mode.

### Second Embodiment

A modified example of the semiconductor device according to the first embodiment will be described, particularly in the case where the power device 20 is turned on again after turn-off to increase the resistance between the source and drain of the power device 20, as shown in FIG. 2B. Note that similar components to those in the first embodiment are denoted by the same reference numerals, and their descriptions may be omitted.

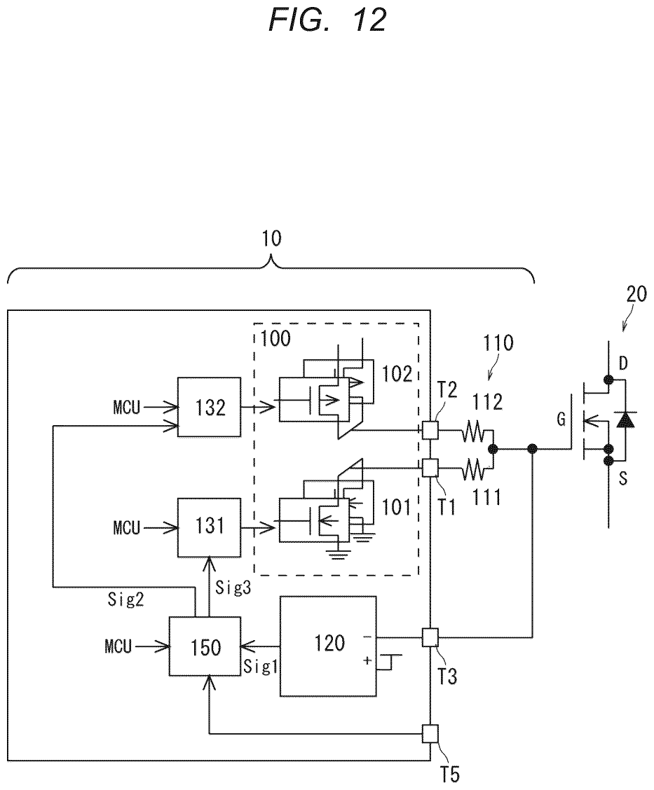

FIG. 12 is a block diagram of a semiconductor device 10 according to this embodiment. The semiconductor device 10 is connected to the power device 20 and includes a gate driver unit 100, a resistance unit 110, a detection circuit 120, a first control circuit 131, a second control circuit 132, and a register circuit 150 with a timer. The first control circuit 131 is connected to the first circuit 101, and the second control circuit 132 is connected to the second circuit 102. The first control circuit 131 and the second control circuit 132 may each be configured with logic circuits and may be connected to a microcontroller unit (MCU).

The detection circuit 120 includes a monitor unit and a comparator. The monitor unit is configured to observe at least one of the gate voltages of the power device 20, the voltage between the source and drain, and the load current. The monitor unit may be provided as a separate circuit external to the semiconductor device 10, but if it is built into the detection circuit 120, additional components are unnecessary, allowing for the miniaturization of the semiconductor device 10.

The comparator compares the electrical characteristics of the power device 20 observed by the monitor unit with a predetermined threshold set in the comparator and is configured to send a signal Sig1 to the register circuit 150 when a comparison result meeting the set conditions is obtained.

In the first embodiment, the first circuit 101 and the second circuit 102 are each a multi-level gate driver circuit with at least two stages, High and Low, but are not limited to this in the present embodiment. For example, even in a configuration where the first circuit 101 is an n-type transistor and the second circuit 102 is a p-type transistor, the semiconductor device 10 according to the present embodiment operates suitably.

In the example of the semiconductor device 10 shown in FIG. 12, the monitor unit observes the gate voltage of the power device 20 via terminal T3, and the comparator is configured to compare the observed gate voltage with a predetermined threshold. The predetermined threshold here is set to the gate voltage at which the power device 20 is considered to be turned off. The comparator sends signal Sig1 to register circuit 150 when the gate voltage of the power device 20 falls below the threshold.

After a predetermined time has elapsed since receiving signal Sig1, the register circuit 150 issues signal Sig2 to the second control circuit 132 to turn the power device 20 back on and sends signal Sig3 to the first control circuit 131 to reduce the slew rate of the gate of the power device 20.

The second control circuit 132, upon receiving signal Sig2, uses the second circuit 102 to turn the power device 20 back on. The first control circuit 131, upon receiving signal Sig3, uses the first circuit 101 to reduce the slew rate of the gate of the power device 20, thereby increasing the resistance between the source and drain of the power device 20.

This allows the resistance between the source and drain of the power device 20 to be appropriately increased after the power device 20 is turned off and then turned back on, enabling the suppression of EMI.

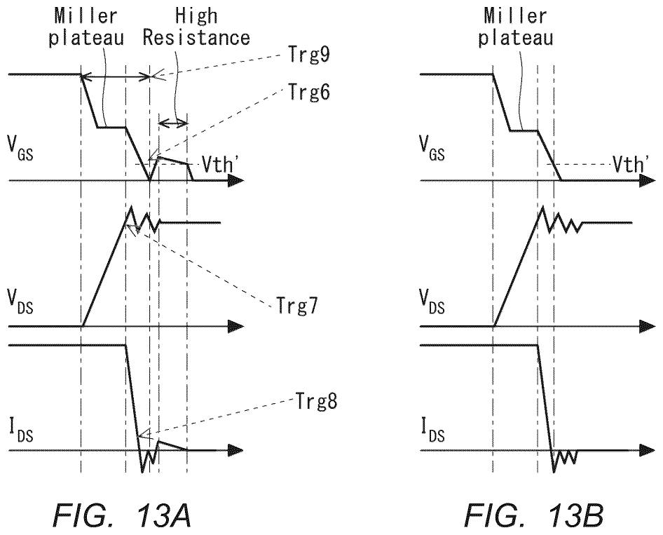

FIGS. 13A and 13B show the electrical characteristics of the power device 20 when it enters a high-resistance mode due to the semiconductor device 10 according to the present embodiment, alongside the electrical characteristics of a comparative example studied by the inventor. FIG. 13A shows the high-resistance mode, and FIG. 13B shows the comparative example, illustrating the time variation of the gate voltage, the voltage between the source and drain, and the load current of the power device 20. As shown in FIG. 13B, ringing occurs in the voltage between the source and drain and the load current in the power device 20 of the comparative example.

In the example shown in FIG. 12, the power device 20 is turned back on by the semiconductor device 10 and enters a high-resistance mode when the gate voltage falls below a predetermined threshold after being turned off, using this point as a trigger (“Trg6” in FIG. 13A). It can be seen that the inclusion of a high-resistance mode period suppresses the ringing of the voltage between the source and drain and the load current.

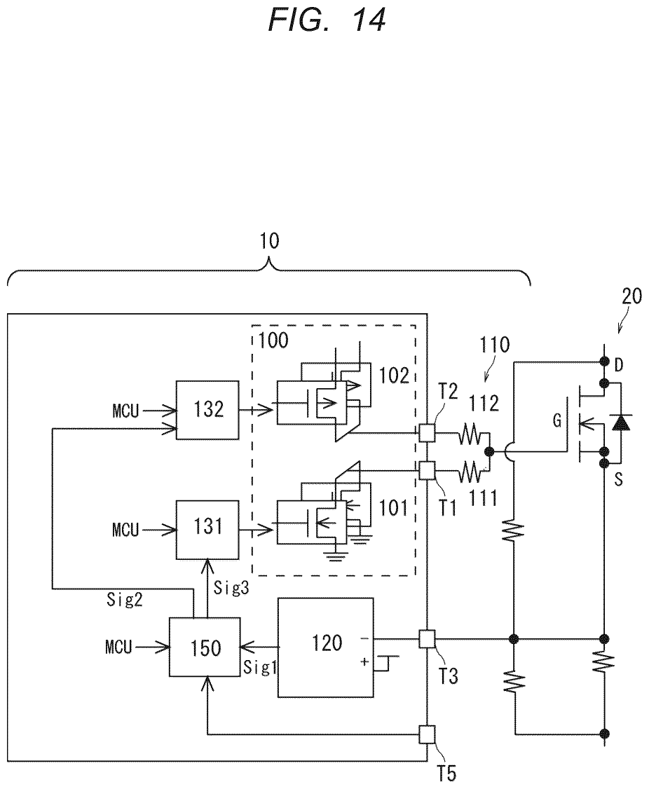

Next, an example of operating the semiconductor device 10 using the voltage between the source and drain of the power device 20 will be described with reference to FIG. 14. In the example of the semiconductor device 10 shown in FIG. 14, the monitor unit observes the voltage between the source and drain of the power device 20 via terminal T3, and the comparator is configured to compare the observed voltage with a predetermined threshold.

The comparator sends signal Sig1 to register circuit 150 when the voltage between the source and drain of the power device 20 exceeds the threshold.

After a predetermined time has elapsed since receiving signal Sig1, the register circuit 150 issues signal Sig2 to the second control circuit 132 to turn the power device 20 back on and sends signal Sig3 to the first control circuit 131 to reduce the slew rate of the gate of the power device 20.

The second control circuit 132, upon receiving signal Sig2, uses the second circuit 102 to turn the power device 20 back on. The first control circuit 131, upon receiving signal Sig3, uses the first circuit 101 to reduce the slew rate of the gate of the power device 20, thereby increasing the resistance between the source and drain of the power device 20.

This allows the resistance between the source and drain of the power device 20 to be appropriately increased after the power device 20 is turned off and then turned back on, enabling the suppression of EMI.

In the example shown in FIG. 14, the power device 20 is turned back on by the semiconductor device 10 and enters a high-resistance mode when the voltage between the source and drain exceeds a predetermined threshold, using this point as a trigger (“Trg7” in FIG. 13A). It can be seen that the inclusion of a high-resistance mode period suppresses the ringing of the voltage between the source and drain and the load current.

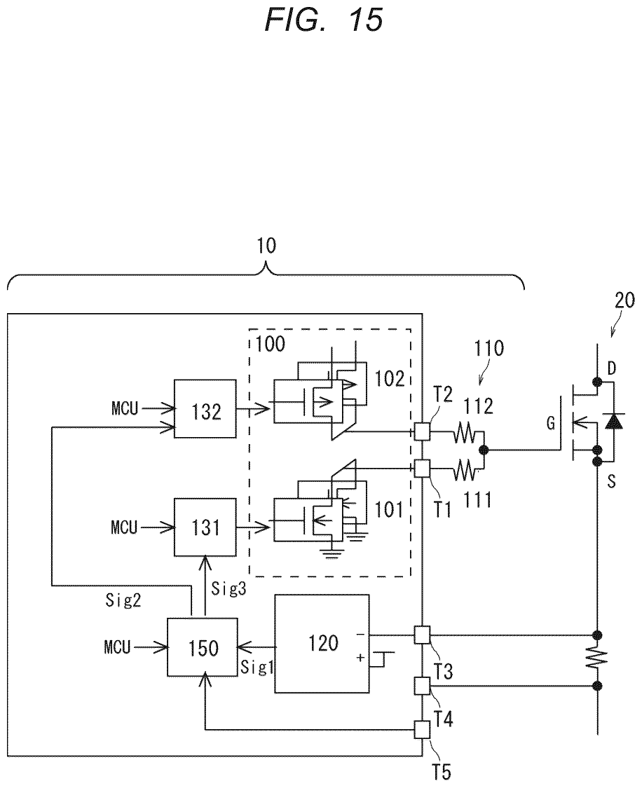

Next, an example of operating the semiconductor device 10 using the load current of the power device 20 will be described with reference to FIG. 15. In the example of the semiconductor device 10 shown in FIG. 15, the monitor unit observes the load current of the power device 20 via terminals T3 and T4, and the comparator is configured to compare the observed load current with a predetermined threshold. Note that the detection of the load current is not limited to the monitor unit and may use the current detection terminal of the power device 20.

The comparator sends signal Sig1 to register circuit 150 when the load current of the power device 20 falls below the threshold.

After a predetermined time has elapsed since receiving signal Sig1, the register circuit 150 issues signal Sig2 to the second control circuit 132 to turn the power device 20 back on and sends signal Sig3 to the first control circuit 131 to reduce the slew rate of the gate of the power device 20.

The second control circuit 132, upon receiving signal Sig2, uses the second circuit 102 to turn the power device 20 back on. The first control circuit 131, upon receiving signal Sig3, uses the first circuit 101 to reduce the slew rate of the gate of the power device 20, thereby increasing the resistance between the source and drain of the power device 20.

This allows the resistance between the source and drain of the power device 20 to be appropriately increased after the power device 20 is turned off and then turned back on, enabling the suppression of EMI.

In the example shown in FIG. 15, the power device 20 is turned back on by the semiconductor device 10 and enters a high-resistance mode when the load current exceeds a predetermined threshold, using this point as a trigger (“Trg8” in FIG. 13A). It can be seen that the inclusion of a high-resistance mode period suppresses the ringing of the voltage between the source and drain and the load current.

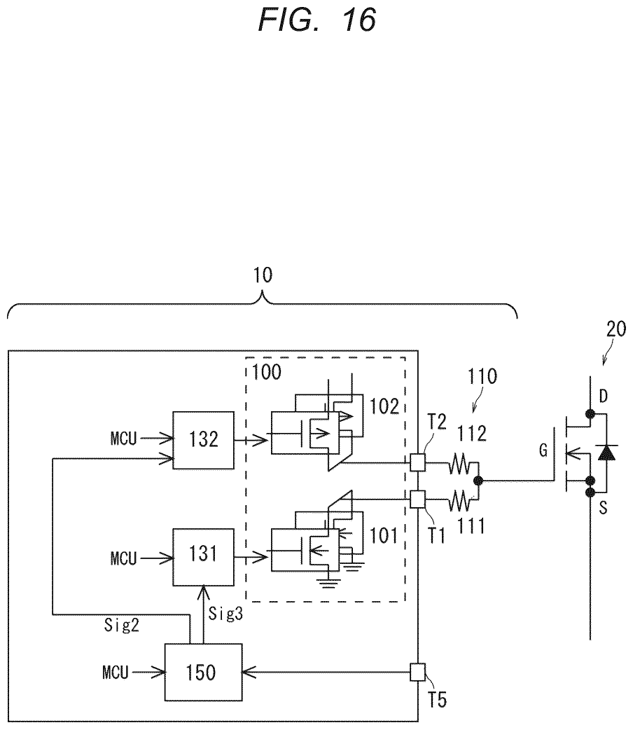

Next, an example of operating the semiconductor device 10 using a timer instead of the detection circuit 120 will be described with reference to FIG. 16. In example of the semiconductor device 10 shown in FIG. 16, a configuration is provided in which a register circuit 150 with a timer is placed upstream of the first control circuit 131 and the second control circuit 132. The register circuit 150 may also be configured to connect to a microcontroller unit (MCU).

When the register circuit 150 detects the start of the turn-off of the power device 20 via terminal T5, it sends a signal Sig2 to the second control circuit 132 to turn the power device 20 back on after a predetermined time and transmits a signal Sig3 to the first control circuit 131 to reduce the slew rate of the gate of the power device 20.

Upon receiving signal Sig2, the second control circuit 132 turns the power device 20 back on using the second circuit 102. Upon receiving signal Sig3, the first control circuit 131 reduces the slew rate of the gate of the power device 20 using the first circuit 101, thereby increasing the resistance between the source and drain of the power device 20.

As a result, after the power device 20 is turned off, it can be turned back on to appropriately increase the resistance between the source and drain of the power device 20, thereby enabling the suppression of EMI.

In the example shown in FIG. 16, the power device 20 is turned back on by the semiconductor device 10 at a point in time after the power device 20 has turned off and a predetermined time has elapsed, using this point as a trigger (“Trg9” in FIG. 13A), and further enters a high-resistance mode. It can be seen that the inclusion of the high-resistance mode period suppresses the ringing of the voltage and load current between the source and drain.

While the invention made by the present inventors has been specifically described based on the embodiments, it goes without saying that the present disclosure is not limited to the embodiments already described, and various modifications are possible without departing from the spirit of the invention.

What is claimed is:

1. A semiconductor device connected to a power device, comprising:
a gate driver unit including a first circuit and a second circuit;
a resistor unit connecting the gate of the power device and the gate driver unit; and
a first control circuit connected to the gate driver unit,
wherein the first control circuit is configured to increase the resistance of the power device by issuing an instruction to reduce the slew rate of the power device to the first circuit during the turn-off of the power device.

2. The semiconductor device according to claim 1, further comprising:
a detection circuit having a monitor unit and a comparator,
wherein the monitor unit is configured to observe the voltage of the gate of the power device, the comparator is configured to compare the observed voltage with a predetermined threshold, and the first control circuit is configured to increase the resistance of the power device when the voltage is below the predetermined threshold.

3. The semiconductor device according to claim 2, wherein the first control circuit is configured to increase the resistance of the power device after the voltage becomes lower than the Miller plateau voltage.

4. The semiconductor device according to claim 1, further comprising:
a detection circuit having a monitor unit and a comparator,
wherein the monitor unit is configured to observe the voltage between the source and drain of the power device, the comparator is configured to compare the observed voltage with a predetermined threshold, and the first control circuit is configured to increase the resistance of the power device when the voltage is above the predetermined threshold.

5. The semiconductor device according to claim 1, further comprising:
a detection circuit having a monitor unit and a comparator,
wherein the monitor unit is configured to observe the load current of the power device, the comparator is configured to compare the observed load current with a predetermined threshold, and the first control circuit is configured to increase the resistance of the power device when the load current is below the predetermined threshold.

6. The semiconductor device according to claim 1, further comprising:
a detection circuit having a monitor unit and a comparator, and a clamp circuit connecting the drain and gate of the power device,
wherein the clamp circuit includes a Zener diode connecting the gate driver unit and the drain of the power device, the comparator is configured to detect ringing by observing the current flowing through the Zener diode, and the first control circuit is configured to increase the resistance of the power device when ringing is detected.

7. The semiconductor device according to claim 1, further comprising:
a register circuit connected to the first control circuit,
wherein the register circuit is configured to issue an instruction to the first control circuit to increase the resistance of the power device after a predetermined time has elapsed from the start of the turn-off of the power device.

8. The semiconductor device according to claim 1, further comprising:
a detection circuit having a monitor unit and a comparator; a second control circuit connected to the second circuit; and
a register circuit connected to the detection circuit, the first control circuit, and the second control circuit,
wherein the monitor unit is configured to observe the voltage of the gate of the power device, the comparator is configured to compare the observed voltage with a predetermined threshold, and the register circuit is configured to issue an instruction to the second control circuit to turn on the power device after a predetermined time has elapsed from detecting that the voltage is below the predetermined threshold, and subsequently issue an instruction to the first control circuit to increase the resistance of the power device.

9. The semiconductor device according to claim 8, wherein the register circuit is configured to issue an instruction to the first control circuit to increase the resistance of the power device after a predetermined time has elapsed from when the voltage becomes lower than the Miller plateau voltage.

10. The semiconductor device according to claim 1, further comprising:
a detection circuit having a monitor unit and a comparator; a second control circuit connected to the second circuit; and
a register circuit connected to the detection circuit, the first control circuit, and the second control circuit,
wherein the monitor unit is configured to observe the voltage between the source and drain of the power device, the comparator is configured to compare the observed voltage with a predetermined threshold, and the register circuit is configured to issue an instruction to the second control circuit to turn on the power device after a predetermined time has elapsed from detecting that the voltage is above the predetermined threshold, and subsequently issue an instruction to the first control circuit to increase the resistance of the power device.

11. The semiconductor device according to claim 1, further comprising:
a detection circuit having a monitor unit and a comparator; a second control circuit connected to the second circuit; and
a register circuit connected to the detection circuit, the first control circuit, and the second control circuit,
wherein the monitor unit is configured to observe the load current of the power device, the comparator is configured to compare the observed load current with a predetermined threshold, and the register circuit is configured to issue an instruction to the second control circuit to turn on the power device after a predetermined time has elapsed from detecting that the load current is below the predetermined threshold, and subsequently issue an instruction to the first control circuit to increase the resistance of the power device.

12. The semiconductor device according to claim 1, further comprising:
a second control circuit connected to the second circuit and a register circuit connected to the first control circuit and the second control circuit,
wherein the register circuit is configured to issue an instruction to the second control circuit to turn on the power device after a predetermined time has elapsed from detecting the start of the turn-off of the power device, and subsequently issue an instruction to the first control circuit to increase the resistance of the power device.
